(19) United States
(12) Patent Application Publication
(10) Pub. No.: US 2018/0083069 A1
(43) Pub. Date: Mar. 22, 2018

(54) COMPLEMENTARY THIN FILM TRANSISTOR AND MANUFACTURING METHOD THEREOF

(71) Applicant: SHENZHEN CHINA STAR OPTOELECTRONICS TECHNOLOGY CO., LTD., Shenzhen, Guangdong (CN)

(72) Inventors: Mian ZENG, Shenzhen (CN); Hsiangchih HSIAO, Shenzhen (CN); Shengdong ZHANG, Shenzhen (CN)

(73) Assignee: SHENZHEN CHINA STAR OPTOELECTRONICS TECHNOLOGY CO., LTD., Shenzhen, Guangdong (CN)

(21) Appl. No.: 15/034,577

(22) PCT Filed: Apr. 8, 2016
(86) PCT No.: PCT/CN2016/078749

§ 371 Date: May 5, 2016

(30) Foreign Application Priority Data
Feb. 29, 2016 (CN) 201610112863.7

(51) Int. Cl. H01L 27/28; H01L 29/24; H01L 29/786; H01L 51/05; H01L 51/10; H01L 29/66; H01L 23/31

(52) U.S. Cl. CPC H01L 27/286; H01L 29/24; H01L 29/7869; H01L 51/0554; H01L 23/3171; H01L 29/78648; H01L 51/107; H01L 29/66969; H01L 27/283

(57) ABSTRACT

A complementary thin film transistor and manufacturing method thereof are provided. The complementary thin film transistor has a substrate, an n-type semiconductor layer, and a p-type semiconductor layer. The substrate defines an n-type transistor region and a p-type transistor region adjacent to the n-type transistor region. The n-type semiconductor layer is disposed above the substrate and within the n-type transistor region, and the n-type semiconductor layer comprises a metal oxide material. The p-type semiconductor layer is disposed above the substrate and within the p-type transistor region, and the p-type semiconductor layer comprises an organic semiconductor material.

### FIELD OF THE INVENTION

The present invention relates to a thin film transistor and a manufacturing method thereof, and more particularly to a complementary thin film transistor and manufacturing method thereof.

### BACKGROUND OF THE INVENTION

Complementary Metal-Oxide-Semiconductor (CMOS) which is a design of integrated circuit process can make components of n-type MOSFET (NMOS) and p-type MOSFET (PMOS) from a silicon wafer template. CMOS means that physical characteristics of NMOS and PMOS are complementarity. SRAM, microcontrollers, microprocessors, CMOS image sensing devices, or other digital logic circuitry can be made from a process of CMOS. CMOS is formed from NMOS and PMOS, and CMOS is a basic circuit construction of an integrated circuit.

A substrate of a display panel is a glass or plastic substrate. Refer to FIG. 1, which is a schematic circuit diagram of a traditional inverter of a Continuous Time Fourier Transform (CTFT). The CTFT connected to a power supply voltage VDD and a common voltage VSS has a p-type thin film transistor 11, and an n-type thin film transistor 12, wherein the n-type thin film transistor 12 is a active component formed on a substrate, and has a input end Vin and a output end Vout.

However, a drive chip and a glass substrate of the traditional liquid crystal display is not made by the design of an integrated separation. In the technology of low temperature poly-silicon (LTPS), the semiconductor of the p-type thin film transistor 11 and the n-type thin film transistor 12 in the CTFT circuit are made by different types of doping. The preparation process of the CTFT circuit has a complex process of laser annealing and ion implantation with a high manufacturing cost.

### SUMMARY OF THE INVENTION

An object of the present invention is to provide a complementary thin film transistor, wherein an n-type thin film transistor is formed within the n-type transistor region and a p-type thin film transistor is formed within the p-type transistor region to form a double-gate structure for improving the device characteristics.

Another object of the present invention is to provide a manufacturing method of a complementary thin film transistor, wherein an n-type thin film transistor is formed within the n-type transistor region and a p-type thin film transistor is formed within the p-type transistor region to simplify the process and reduce the manufacturing cost.

To achieve the above object, the present invention provides a complementary thin film transistor, the complementary thin film transistor comprises a substrate, an n-type semiconductor layer, and a p-type semiconductor layer. The substrate defines as an n-type transistor region and a p-type transistor region adjacent to the n-type transistor region. The n-type semiconductor layer is disposed above the substrate and within the n-type transistor region, wherein the n-type semiconductor layer comprises a metal oxide material. The p-type semiconductor layer is disposed above the substrate and within the p-type transistor region, wherein the p-type semiconductor layer comprises an organic semiconductor material.

In one embodiment of the present invention, the complementary thin film transistor further includes a first gate layer and an insulation layer, the first gate layer is formed on the substrate and disposed within the n-type transistor region and the p-type transistor region, the insulation layer is formed on the first gate layer and the substrate, and wherein the n-type semiconductor layer and the p-type semiconductor layer are formed on the insulation layer and spaced apart from each other.

In one embodiment of the present invention, the complementary thin film transistor further includes an etched barrier layer formed on the n-type semiconductor layer and the insulation layer, and disposed within the n-type transistor region.

In one embodiment of the present invention, the complementary thin film transistor further includes an electrode metal layer formed on the insulation layer and disposed within the n-type transistor region and the p-type transistor region, the electrode metal layer is formed on the n-type semiconductor layer, and the p-type semiconductor layer is formed on the electrode metal layer.

In one embodiment of the present invention, the complementary thin film transistor further includes a passivation layer and a second gate layer, the passivation layer is formed on the electrode metal layer and the insulation layer and disposed within the n-type transistor region and the p-type transistor region, and the second gate layer is formed on the passivation layer and disposed within the n-type transistor region and the p-type transistor region.

In one embodiment of the present invention, the metal oxide material of the n-type semiconductor layer is selected from an indium gallium zinc oxide, an indium zinc oxide, or a zinc tin oxide.

In one embodiment of the present invention, the organic semiconductor material of the p-type semiconductor layer is selected from pentacene, triphenylamine, fullerene, phthalocyanine, perylene derivative, or cyanine.

To achieve the above object, the present invention provides a manufacturing method of a complementary thin film transistor, the method comprises steps of: a first gate layer formation step for defining an n-type transistor region and a p-type transistor region adjacent to the n-type transistor region on a substrate, and forming a first gate layer on the substrate, wherein the first gate layer is disposed within the n-type transistor region and the p-type transistor region; an insulation layer formation step for forming an insulation layer on the first gate layer and the substrate; an n-type semiconductor layer formation step for forming an n-type semiconductor layer on the insulation layer, wherein the n-type semiconductor layer is disposed within the n-type transistor region and comprises a metal oxide material; an electrode metal layer formation step for forming an electrode metal layer on the n-type transistor region and the insulation layer, wherein the electrode metal layer is disposed within the n-type transistor region and the p-type transistor region; and a p-type semiconductor layer formation step for forming a p-type semiconductor layer on the insulation layer and the electrode metal layer, wherein the p-type semiconductor layer is disposed within the p-type transistor region and comprises an organic semiconductor material, and the n-type semiconductor layer and the p-type semiconductor layer are spaced apart from each other.

In one embodiment of the present invention, after the n-type semiconductor layer formation step, the manufacturing method further comprises an etched barrier layer formation step for forming an etched barrier layer on the n-type semiconductor layer and the insulation layer, wherein the etched barrier layer is disposed within the n-type transistor region.

In one embodiment of the present invention, after the p-type semiconductor layer formation step, the manufacturing method further comprises a second gate layer formation step for forming a passivation layer on the electrode metal layer and the insulation layer, and forming a second gate layer on the passivation layer, wherein the passivation layer is disposed within the n-type transistor region and the p-type transistor region, and the second gate layer is disposed within the n-type transistor region and the p-type transistor region.

As described above, in the complementary thin film transistor of the present invention, an n-type thin film transistor is formed within the n-type transistor region and a p-type thin film transistor is formed within the p-type transistor region to simplify the process and reduce the manufacturing cost. The n-type thin film transistor and the p-type thin film transistor are also made to form a double-gate structure for improving the device characteristics.

### DESCRIPTION OF THE DRAWINGS

FIG. 1 is a schematic circuit diagram of a traditional inverter of a Continuous Time Fourier Transform.

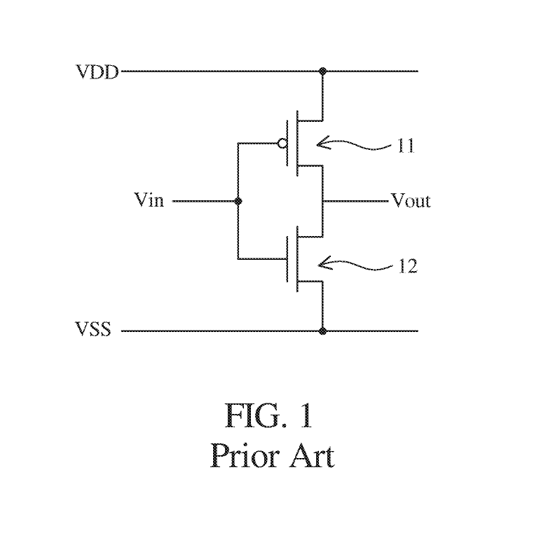

FIG. 2 is a cross-sectional view of a complementary thin film transistor according to a first preferred embodiment of the present invention.

FIG. 3 is a cross-sectional view of a complementary thin film transistor according to a second preferred embodiment of the present invention.

FIG. 4 is a flowchart of a manufacturing method of a complementary thin film transistor according to a first preferred embodiment of the present invention.

FIG. 5 is a flowchart of a manufacturing method of a complementary thin film transistor according to a second preferred embodiment of the present invention.

### DETAILED DESCRIPTION OF THE PREFERRED EMBODIMENTS

The structure and the technical means adopted by the present invention to achieve the above and other objects can be best understood by referring to the following detailed description of the preferred embodiments and the accompanying drawings. Furthermore, directional terms described by the present invention, such as upper, lower, front, back, left, right, inner, outer, side, longitudinal/vertical, transverse/horizontal, and etc., are only directions by referring to the accompanying drawings, and thus the used directional terms are used to describe and understand the present invention, but the present invention is not limited thereto.

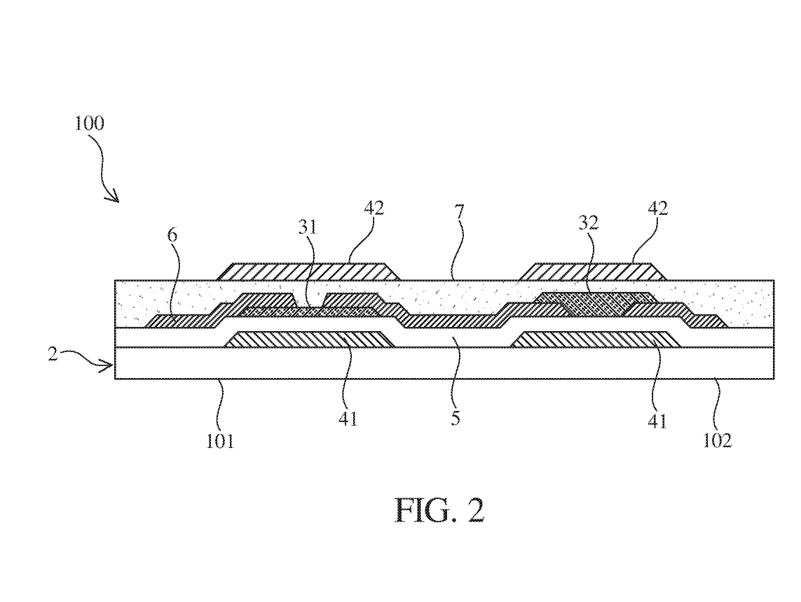

Refer to FIG. 2, which is a cross-sectional view of a complementary thin film transistor 100 according to a first preferred embodiment of the present invention, wherein the complementary thin film transistor 100 has a substrate 2, an n-type semiconductor layer 31, a p-type semiconductor layer 32, a first gate layer 41, a insulation layer 5, an electrode metal layer 6, a passivation layer 7, and a second gate layer 42. The detailed structure of each component, assembly relationships, and principle of operation in the present invention will be described in detail hereinafter.

Refer still to FIG. 2, the substrate 2 defines an n-type transistor region 101 and a p-type transistor region 102 adjacent to the n-type transistor region 101, wherein the substrate 2 is a glass substrate in the first preferred embodiment, and the substrate 2 is also a polyethylene terephthalate substrate in another preferred embodiment.

Refer to FIG. 2, the n-type semiconductor layer 31 is disposed above the substrate 2 and within the n-type transistor region 101, wherein the n-type semiconductor layer 31 comprises a metal oxide material, and the metal oxide material of the n-type semiconductor layer 31 is selected from an indium gallium zinc oxide, an indium zinc oxide, or a zinc tin oxide in the first preferred embodiment.

Refer still to FIG. 2, the p-type semiconductor layer 32 is disposed above the substrate 2 and within the p-type transistor region 102, wherein the p-type semiconductor layer 32 comprises an organic semiconductor material, and the organic semiconductor material of the p-type semiconductor layer 32 is selected from pentacene, triphenylamine, fullerene, phthalocyanine, perylene derivative, or cyanine in the first preferred embodiment.

Refer still to FIG. 2, the first gate layer 41 is formed on the substrate 2, and two portions of the first gate layer 41 are disposed within the n-type transistor region 101 and the p-type transistor region 102 respectively, wherein the first gate layer 41 is a metal material, such as Aluminum, manganese, copper, titanium or alloy thereof in the first preferred embodiment.

Refer still to FIG. 2, the insulation layer 5 is formed on the first gate layer 41 and the substrate 2, wherein the n-type semiconductor layer 31 and the p-type semiconductor layer 32 are formed on the insulation layer 5 and spaced apart from each other, and the insulation layer 5 is formed for insulating from the first gate layer 41 in the first preferred embodiment.

Refer still to FIG. 2, the electrode metal layer 6 is formed on the insulation layer 5 and disposed within the n-type transistor region 101 and the p-type transistor region 102, wherein the electrode metal layer 6 is formed on the n-type semiconductor layer 31, the p-type semiconductor layer 32 is formed on the electrode metal layer 6, and the electrode metal layer 6 is a metal material, such as Aluminum, manganese, copper, titanium or alloy thereof in the first preferred embodiment. Furthermore, the n-type semiconductor layer 31 is formed on the insulation layer 5 by exposure, development, etching, and stripped, and the n-type semiconductor layer 31 is sputtered on the electrode metal layer 6 and coats the p-type semiconductor layer 32 (organic semiconductor material layer). A organic thin film transistor (organic TFT) can be made to be a area structure of the p-type thin film transistor, and an oxide thin film transistor (oxide TFT) can be made to be a area structure of the n-type thin film transistor by disposing the n-type semiconductor layer 31 and the p-type semiconductor layer 32 on different layers. Thus a double-gate structure can be formed to simplify the process and to improve the device characteristics.

Refer still to FIG. 2, the passivation layer 7 is formed on the electrode metal layer 6 and the insulation layer 5 and disposed within the n-type transistor region 101 and the p-type transistor region 102.

Refer still to FIG. 2, the second gate layer 42 is formed on the passivation layer 7, and two portions of the second gate layer 42 are disposed within the n-type transistor region 101 and the p-type transistor region 102 respectively.

According to a structure of the present invention, the n-type thin film transistor is formed within the n-type transistor region 101 and the p-type thin film transistor is formed within the p-type transistor region 102 through disposing the n-type semiconductor layer 31 and the p-type semiconductor layer 32 above the substrate 2, so that the organic TFT can be made to be the area structure of the p-type thin film transistor, and the oxide TFT can be made to be the area structure of the n-type thin film transistor. In addition, the n-type thin film transistor and the p-type thin film transistor are also made to form a double-gate structure for simplifying the process and improving the device characteristics, such as increasing a on-state current (Ion), reducing off-state current (Ioff), and improving the shift of voltage Vth without additional cost.

As described above, the n-type thin film transistor is formed within the n-type transistor region 101 and the p-type thin film transistor is formed within the p-type transistor region 102, the process is simple and the manufacturing cost is low, and the n-type thin film transistor and the p-type thin film transistor are also made to form a double-gate structure for simplifying the process and improving the device characteristics, such as increasing a on-state current (Ion), reducing off-state current (Ioff), and improving the shift of voltage Vth without additional cost.

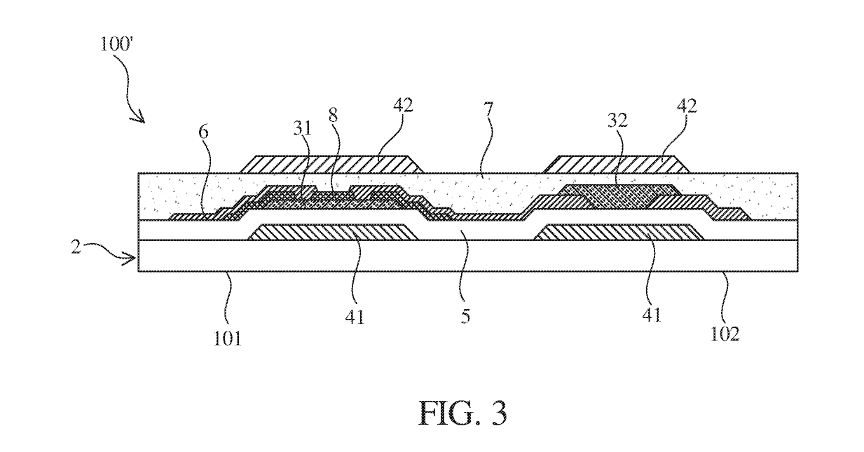

Refer to FIG. 3, which is a cross-sectional view of a complementary thin film transistor 100′ according to a second preferred embodiment of the present invention, and is similar to the first preferred embodiment, wherein the complementary thin film transistor 100′ has a substrate 2, an n-type semiconductor layer 31, a p-type semiconductor layer 32, a first gate layer 41, a insulation layer 5, an electrode metal layer 6, a passivation layer 7, and a second gate layer 42. As shown, the difference of the second preferred embodiment is that the complementary thin film transistor 100′ further includes an etched barrier layer 8 formed on the n-type semiconductor layer 31 and the insulation layer 5, and the etched barrier layer 8 is disposed within the n-type transistor region 101 to protect the n-type semiconductor layer 31 which is an n-type channel. Furthermore, the etched barrier layer 8 is formed on the n-type semiconductor layer 31 and the insulation layer 5 which near an edge of the n-type semiconductor layer 31 a channel is formed on a portion of the etched barrier layer 8 on the n-type semiconductor layer 31 for disposing the electrode metal layer 6, so that a portion of the n-type semiconductor layer 31 and the electrode metal layer 6 can be electrically connected.

As described above, the n-type thin film transistor is formed within the n-type transistor region 101 and the p-type thin film transistor is formed within the p-type transistor region 102, the process is simple and the manufacturing cost is low, and the n-type thin film transistor and the p-type thin film transistor are also made to form a double-gate structure for simplifying the process and improving the device characteristics. In addition, the etched barrier layer 8 is formed on the n-type semiconductor layer 31 to protect the n-type semiconductor layer 31 which is an n-type channel.

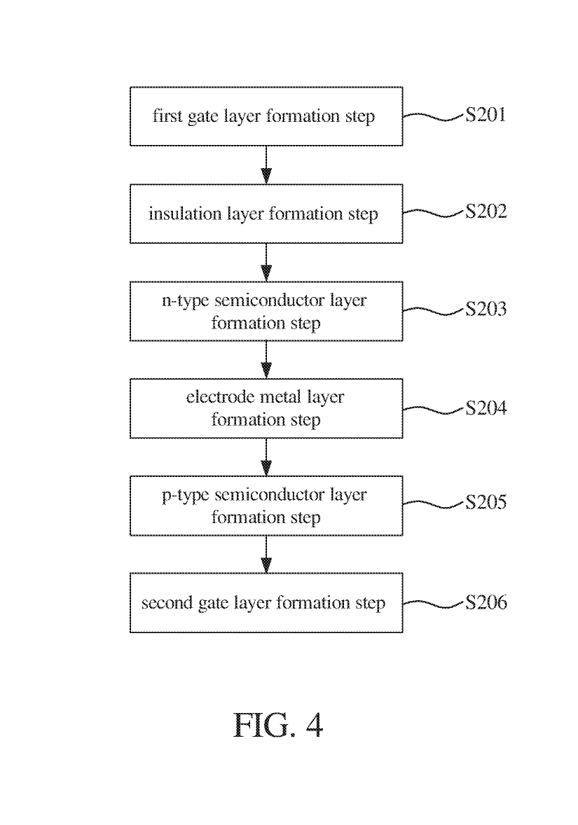

Refer to FIG. 4 with reference FIG. 2, which is a flowchart of a manufacturing method of a complementary thin film transistor according to a first preferred embodiment of the present invention is illustrated. As shown, the measuring method comprises a first gate layer formation step S201, an insulation layer formation step S202, an n-type semiconductor layer formation step S203, an electrode metal layer formation step S204, a p-type semiconductor layer formation step S205, and a second gate layer formation step S206.

Refer still to FIG. 4 with reference FIG. 2, in the first gate layer formation step S201, a substrate 2 is defined an n-type transistor region 101 and a p-type transistor region 102 adjacent to the n-type transistor region 101, and a first gate layer 41 is formed on the substrate 2, and disposed within the n-type transistor region 101 and the p-type transistor region 102.

Refer still to FIG. 4 with reference FIG. 2, in the insulation layer formation step S202, an insulation layer 5 is formed on the first gate layer 41 and the substrate 2.

Refer still to FIG. 4 with reference FIG. 2, in the n-type semiconductor layer formation step S203, an n-type semiconductor layer 31 is formed on the insulation layer 5 within the n-type transistor region 101, wherein the n-type semiconductor layer 31 comprises a metal oxide material.

Refer still to FIG. 4 with reference FIG. 2, in the electrode metal layer formation step S204, an electrode metal layer 6 is formed on the n-type semiconductor layer 31 and the insulation layer 5, and disposed within the n-type transistor region 101 and the p-type transistor region 102.

Refer still to FIG. 4 with reference FIG. 2, in the p-type semiconductor layer formation step S205, a p-type semiconductor layer 32 is formed on the insulation layer 5 and the electrode metal layer 6, and disposed within the p-type transistor region 102, wherein the p-type semiconductor layer 32 comprises an organic semiconductor material, and the n-type semiconductor layer 31 and the p-type semiconductor layer 32 are spaced apart from each other.

Refer still to FIG. 4 with reference FIG. 2, in the second gate layer formation step S206, a passivation layer 7 is formed on the electrode metal layer 6 and the insulation layer 5, and disposed within the n-type transistor region 101 and the p-type transistor region 102, and then a second gate layer 42 is formed on the passivation layer 7, and disposed within the n-type transistor region 101 and the p-type transistor region 102.

As described above, the n-type thin film transistor is formed within the n-type transistor region 101 and the p-type thin film transistor is formed within the p-type transistor region 102, the process is simple and the manufacturing cost is low, and the n-type thin film transistor and the p-type thin film transistor are also made to form a double-gate structure for simplifying the process and improving the device characteristics, such as increasing a on-state current (Ion), reducing off-state current (Ioff), and improving the shift of voltage Vth without additional cost. The p-type semiconductor layer formation step S205 is implemented after the n-type semiconductor layer formation step S203, so that the semiconductor characteristics of the n-type thin film transistor cannot be influenced by the process.

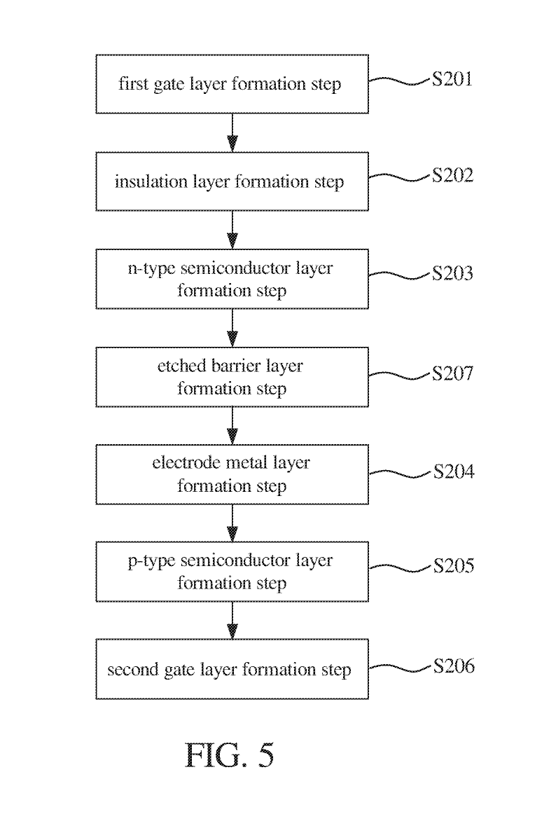

Refer to FIG. 5 with reference FIG. 3, which is a flowchart of a manufacturing method of a complementary thin film transistor according to a second preferred embodiment of the present invention. As shown, the measuring method comprises a first gate layer formation step S201, an insulation layer formation step S202, an n-type semiconductor layer formation step S203, an etched barrier layer formation step S207, an electrode metal layer formation step S204, a p-type semiconductor layer formation step S205, and a second gate layer formation step S206.

Refer still to FIG. 5 with reference FIG. 3, in the first gate layer formation step S201, a substrate 2 is defined an n-type transistor region 101 and a p-type transistor region 102 adjacent to the n-type transistor region 101, and a first gate layer 41 is formed on the substrate 2, and disposed within the n-type transistor region 101 and the p-type transistor region 102.

Refer still to FIG. 5 with reference FIG. 3, in the insulation layer formation step S202, an insulation layer 5 is formed on the first gate layer 41 and the substrate 2.

Refer still to FIG. 5 with reference FIG. 3, in the n-type semiconductor layer formation step S203, an n-type semiconductor layer 31 is formed on the insulation layer 5 within the n-type transistor region 101, wherein the n-type semiconductor layer 31 comprises a metal oxide material.

Refer still to FIG. 5 with reference FIG. 3, in etched barrier layer formation step S207, an etched barrier layer 8 is formed on the n-type semiconductor layer 31 and the insulation layer 5, and the etched barrier layer 8 is disposed within the n-type transistor region 101.

Refer still to FIG. 5 with reference FIG. 3, in the electrode metal layer formation step S204, an electrode metal layer 6 is formed on the n-type semiconductor layer 31 and the insulation layer 5, and disposed within the n-type transistor region 101 and the p-type transistor region 102.

Refer still to FIG. 5 with reference FIG. 3, in the p-type semiconductor layer formation step S205, a p-type semiconductor layer 32 is formed on the insulation layer 5 and the electrode metal layer 6, and disposed within the p-type transistor region 102, wherein the p-type semiconductor layer 32 comprises an organic semiconductor material, and the n-type semiconductor layer 31 and the p-type semiconductor layer 32 are spaced apart from each other.

Refer still to FIG. 5 with reference FIG. 3, in the second gate layer formation step S206, a passivation layer 7 is formed on the electrode metal layer 6 and the insulation layer 5, and disposed within the n-type transistor region 101 and the p-type transistor region 102, and then a second gate layer 42 is formed on the passivation layer 7, and disposed within the n-type transistor region 101 and the p-type transistor region 102.

As described above, the n-type thin film transistor is formed within the n-type transistor region 101 and the p-type thin film transistor is formed within the p-type transistor region 102, the process is simple and the manufacturing cost is low, and the n-type thin film transistor and the p-type thin film transistor are also made to form a double-gate structure for simplifying the process and improving the device characteristics. In addition, the etched barrier layer 8 is formed on the n-type semiconductor layer 31 to protect the n-type semiconductor layer 31 which is an n-type channel.

The present invention has been described with preferred embodiments thereof and it is understood that many changes and modifications to the described embodiments can be carried out without departing from the scope and the spirit of the invention that is intended to be limited only by the appended claims.

What is claimed is:

1. A complementary thin film transistor, comprising:
a substrate defined an n-type transistor region and a p-type transistor region adjacent to the n-type transistor region;
an n-type semiconductor layer disposed above the substrate and within the n-type transistor region, wherein the n-type semiconductor layer comprises a metal oxide material, and the metal oxide material of the n-type semiconductor layer is selected from an indium gallium zinc oxide, an indium zinc oxide, or a zinc tin oxide; and
a p-type semiconductor layer disposed above the substrate and within the p-type transistor region, wherein the p-type semiconductor layer comprises an organic semiconductor material, and the organic semiconductor material of the p-type semiconductor layer is selected from pentacene, triphenylamine, fullerene, phthalocyanine, perylene derivative, or cyanine.

2. The complementary thin film transistor according to claim 1, wherein the complementary thin film transistor further includes a first gate layer and an insulation layer, the first gate layer is formed on the substrate and disposed within the n-type transistor region and the p-type transistor region, the insulation layer is formed on the first gate layer and the substrate, and wherein the n-type semiconductor layer and the p-type semiconductor layer are formed on the insulation layer and spaced apart from each other.

3. The complementary thin film transistor according to claim 2, wherein the complementary thin film transistor further includes an electrode metal layer formed on the insulation layer and disposed within the n-type transistor region and the p-type transistor region, the electrode metal layer is formed on the n-type semiconductor layer, and the p-type semiconductor layer is formed on the electrode metal layer.

4. The complementary thin film transistor according to claim 2, wherein the complementary thin film transistor further includes a passivation layer and a second gate layer, the passivation layer is formed on the electrode metal layer and the insulation layer and disposed within the n-type transistor region and the p-type transistor region, and the second gate layer is formed on the passivation layer and disposed within the n-type transistor region and the p-type transistor region.

5. The complementary thin film transistor according to claim 2, wherein the complementary thin film transistor further includes an etched barrier layer formed on the n-type semiconductor layer and the insulation layer, and disposed within the n-type transistor region.

6. The complementary thin film transistor according to claim 5, wherein the complementary thin film transistor further includes an electrode metal layer formed on the insulation layer and disposed within the n-type transistor region and the p-type transistor region, the electrode metal layer is formed on the n-type semiconductor layer, and the p-type semiconductor layer is formed on the electrode metal layer.

7. The complementary thin film transistor according to claim 5, wherein the complementary thin film transistor further includes a passivation layer and a second gate layer, the passivation layer is formed on the electrode metal layer and the insulation layer and disposed within the n-type transistor region and the p-type transistor region, and the second gate layer is formed on the passivation layer and disposed within the n-type transistor region and the p-type transistor region.

8. A complementary thin film transistor, comprising:
a substrate defined an n-type transistor region and a p-type transistor region adjacent to the n-type transistor region;
an n-type semiconductor layer disposed above the substrate and within the n-type transistor region, wherein the n-type semiconductor layer comprises a metal oxide material; and
a p-type semiconductor layer disposed above the substrate and within the p-type transistor region, wherein the p-type semiconductor layer comprises an organic semiconductor material.

9. The complementary thin film transistor according to claim 8, wherein the complementary thin film transistor further includes a first gate layer and an insulation layer, the first gate layer is formed on the substrate and disposed within the n-type transistor region and the p-type transistor region, the insulation layer is formed on the first gate layer and the substrate, and wherein the n-type semiconductor layer and the p-type semiconductor layer are formed on the insulation layer and spaced apart from each other.

10. The complementary thin film transistor according to claim 9, wherein the complementary thin film transistor further includes an electrode metal layer formed on the insulation layer and disposed within the n-type transistor region and the p-type transistor region, the electrode metal layer is formed on the n-type semiconductor layer, and the p-type semiconductor layer is formed on the electrode metal layer.

11. The complementary thin film transistor according to claim 9, wherein the complementary thin film transistor further includes a passivation layer and a second gate layer, the passivation layer is formed on the electrode metal layer and the insulation layer and disposed within the n-type transistor region and the p-type transistor region, and the second gate layer is formed on the passivation layer and disposed within the n-type transistor region and the p-type transistor region.

12. The complementary thin film transistor according to claim 9, wherein the complementary thin film transistor further includes an etched barrier layer formed on the n-type semiconductor layer and the insulation layer, and disposed within the n-type transistor region.

13. The complementary thin film transistor according to claim 12, wherein the complementary thin film transistor further includes an electrode metal layer formed on the insulation layer and disposed within the n-type transistor region and the p-type transistor region, the electrode metal layer is formed on the n-type semiconductor layer, and the p-type semiconductor layer is formed on the electrode metal layer.

14. The complementary thin film transistor according to claim 12, wherein the complementary thin film transistor further includes a passivation layer and a second gate layer, the passivation layer is formed on the electrode metal layer and the insulation layer and disposed within the n-type transistor region and the p-type transistor region, and the second gate layer is formed on the passivation layer and disposed within the n-type transistor region and the p-type transistor region.

15. The complementary thin film transistor according to claim 8, wherein the metal oxide material of the n-type semiconductor layer is selected from an indium gallium zinc oxide, an indium zinc oxide, or a zinc tin oxide.

16. The complementary thin film transistor according to claim 8, wherein the organic semiconductor material of the p-type semiconductor layer is selected from pentacene, triphenylamine, fullerene, phthalocyanine, perylene derivative, or cyanine.

17. A manufacturing method of a complementary thin film transistor, comprising steps of:
a first gate layer formation step for defining an n-type transistor region and a p-type transistor region adjacent to the n-type transistor region on a substrate, and forming a first gate layer on the substrate, wherein the first gate layer is disposed within the n-type transistor region and the p-type transistor region;
an insulation layer formation step for forming an insulation layer on the first gate layer and the substrate;
an n-type semiconductor layer formation step for forming an n-type semiconductor layer on the insulation layer, wherein the n-type semiconductor layer is disposed within the n-type transistor region and comprises a metal oxide material;
an electrode metal layer formation step for forming an electrode metal layer on the n-type transistor region and the insulation layer, wherein the electrode metal layer is disposed within the n-type transistor region and the p-type transistor region; and
a p-type semiconductor layer formation step for forming a p-type semiconductor layer on the insulation layer and the electrode metal layer, wherein the p-type semiconductor layer is disposed within the p-type transistor region and comprises an organic semiconductor material, and the n-type semiconductor layer and the p-type semiconductor layer are spaced apart from each other.

18. The manufacturing method according to claim 17, wherein after the n-type semiconductor layer formation step, the manufacturing method further comprises an etched barrier layer formation step for forming an etched barrier layer on the n-type semiconductor layer and the insulation layer, wherein the etched barrier layer is disposed within the n-type transistor region.

19. The manufacturing method according to claim 17, wherein after the p-type semiconductor layer formation step, the manufacturing method further comprises a second gate layer formation step for forming a passivation layer on the electrode metal layer and the insulation layer, and forming a second gate layer on the passivation layer, wherein the passivation layer is disposed within the n-type transistor region and the p-type transistor region, and the second gate layer is disposed within the n-type transistor region and the p-type transistor region.
